(19) United States
(12) Patent Application Publication
(10) Pub. No.: US 2015/0166332 A1
(43) Pub. Date: Jun. 18, 2015

(54) NEMS CONTROL DEVICE HAVING A DIGITAL DELAY MODULE

(71) Applicant: Commissariat a l'energie atomique et aux ene alt, Paris (FR)

(72) Inventor: Gerard Billiot, St Nazaire Les Eymes (FR)

(73) Assignee: Commissariat a l'energie atomique et aux ene alt, Paris (FR)

(21) Appl. No.: 14/390,555

(22) PCT Filed: Apr. 2, 2013
(86) PCT No.: PCT/EP2013/056912

§ 371 Date: Oct. 3, 2014

(30) Foreign Application Priority Data
Apr. 3, 2012 (FR) 12 53040

(51) Int. Cl. B81B 7/00

(52) U.S. Cl. CPC B81B 7/008

(57) ABSTRACT

The present application relates to a device for controlling a micro-electromechanical system MEMS or a nano-electromechanical system NEMS comprising a feedback loop provided with:
means (130) for digitizing at least one analog signal from said MEMS or said NEMS and for delivering a given digital signal,
a programmable delay module (170) for inducing a given delay selected from a plurality of predetermined delays to said given digital signal and delivering one or more delayed digital signals according to said given delay to excitation means of the MEMS or NEMS.

### TECHNICAL FIELD AND PRIOR ART

This application relates to the field of electromechanical systems and in particular that of MEMS (Micro-Electro-Mechanical Systems) or NEMS (Nano Electro-Mechanical Systems).

It provides a feedback device provided with (a) programmable delay module(s) enabling a MEMS or NEMS component to be oscillated and/or kept in oscillation.

The controlling device according to the invention is adapted to a wide range of NEMS or MEMS.

### PRIOR ART

Among the existing NEMS devices, those called “Cross-Beam” are equipped with a movable element 15, which may for example be in the form of a nanoscale beam or a bar designed to vibrate or oscillate (FIGS. 1A and 1B).

This movable element 15 is moved through electrostatic actuating means comprising a connection network on which an excitation signal is applied, the connection network terminating in one or more pads 21, 22 arranged in proximity of the movable element 15.

The excitation signal is generally a signal having a high frequency or a frequency higher than 100 kHz.

Detecting means, which can be for example piezoresistive sensing means comprising piezoresistive gauges enable a detection of the electrical signal generated by the movements of the movable element 15 to be carried out.

These detecting means may comprise a pad 28 connected to a conductive line for extracting a detection signal reflecting a movement of the movable element.

The device may also comprise bias means provided with pads 24, 25, on which a bias signal, generally in the form of a DC voltage, is applied.

The document “A High Gain-Bandwidth Product Transimpedance Amplifier for MEMS-Based Oscillators” Nabki et al., IEEE 2008, for example, discloses a MEMS resonator provided with a movable element in the form of a beam and arranged in a feedback loop provided with a transimpedance amplifier.

The document “Fully Monolithic CMOS nickel micromechanical resonator oscillator”, Huang et al. MEMS 2008 provides a MEMS device provided with a movable element in the form of movable plates linked together through beams and which device may be integrated into a feedback loop comprising an adjustable gain transresistor amplifier.

The document “CMOS MEMS Oscillator for Gas Chemical Detection,” Bedair et al., IEEE 2004, discloses in turn a microelectronic device provided with a MEMS resonator and a pre-amplifier, a phase compensation amplifier and a spectrum analyzer forming a closed loop system.

In order to oscillate and keep oscillating a NEMS or MEMS device, conditions called “Barkhausen” conditions of gain and phase shift should preferably be met.

The document U.S. 2010/0308931 discloses a MEMS controlling device as a feedback loop provided with an analog circuit for inducing a delay or phase shift, this phase shift being adjustable.

The phase shift generated by this circuit can in turn be variable depending on the oscillation frequencies of the MEMS. With such a control circuit, for high frequencies, the analog delay circuit is likely to introduce a significant attenuation of the signal for exciting the MEMS.

The document “Digital Oscillator Circuit using Synchronous Pulse Driving” of Roubicek et al., IEEE 2008 provides a controlling device of an electromechanical system with feedback loop in which digitizing is implemented, the device being provided with a means for introducing a phase shift.

The problem of implementing an improved MEMS microelectronic device capable of oscillating in a wide range of used frequencies and resonators occurs.

### SUMMARY OF THE INVENTION

The present invention first relates to a device for controlling a MEMS micro-electro-mechanical system or NEMS nano-electromechanical system comprising a feedback loop, provided with:
means for digitizing at least one analog signal from said MEMS or said NEMS and for delivering a digital signal,
a programmable delay module to induce a delay selected from a plurality of predetermined delays to said given digital signal and delivering one or more delayed digital signals to energizing means of the MEMS or NEMS.

The digital signal output from the digitizing means and the signal that is fed back to the input of the electromechanical system are thus advantageously of the same frequency and phase-shifted by a phase shift corresponding to the delay programmed by means of the delay module.

The programmable delay module is configured such that to induce a delay to the digital signal, it does not require, in contrast to the devices according to the prior art, to perform a frequency synthesis.

The digitizing means can be in the form of a comparator.

To fulfil the oscillation conditions of the MEMS or NEMS, and overcome the phase shift introduced by the different elements of a feedback loop, a known and controlled phase shift is implemented.

Digitizing said given signal that is desired to be delayed, and said delay module enable a phase shift to be introduced without attenuating this signal and regardless of the signal frequency.

Thus, the controlling device according to the invention can be adapted to a wide range of MEMS and/or NEMS.

According to a first excitation mode of the MEMS or NEMS, the delayed digital signals may be a first signal of a frequency equal to the resonance frequency of the MEMS or NEMS and a second signal of a frequency equal to the resonance frequency of the MEMS or NEMS, the first signal and the second signal being preferably of the same amplitude and being in opposite phases.

The programmable delay module may comprise:
means for delivering a plurality of signals which one phase-shifted with respect to an input signal of said delay unit, said signals being phase-shifted respectively by a plurality of predetermined phase shifts,
selecting means for selecting at least one phase-shifted signal from said plurality of phase-shifted signals,
means for selecting a frequency between a frequency equal to the frequency of said signal and a frequency equal to half the frequency of said input signal, the signal(s) output from said programmable delay module having a phase shift equal to the phase of said phase-shifted signal and a frequency equal to the frequency or half the frequency of said input signal.

The programmable delay module may further comprise means forming a phase-locked loop,

the means for delivering a plurality of phase-shifted signals comprising a voltage-controlled delay line having a first input receiving said digital signal and delivering a feedback signal, the control voltage of the delay line depending on a difference between said digital signal and said feedback signal.

The delay introduced by the delay module is thus a locked delay independent of the voltages and amplitude of the inputted signal thereof. The controlling device may further comprise: means for measuring frequency of said digital signal.

The controlling device may further include a configuration selecting module having a first input connected to the digitizing means and a second input, the configuration selecting module being also provided with a first output and a second output connected to the programmable delay module.

The configuration selecting module can be provided to assume:
a first configuration, wherein the first input is connected to the second output, the second input being connected to the first output,
a second configuration in which the first input is connected to the first output, the second input being connected to the second output.

The configuration selecting module can thus enable the feedback loop to be placed in an open loop configuration, wherein the measurements of delay introduced by the elements of the controlling device can be made, and in another, closed loop, configuration.

The configuration selecting module can be provided such that:

Tp_{(ET/ST)-config1}=Tp_{(CS/ST)-config2}+Tp_{(ET/CE)-config2} and Tp_{(CE/CS)-config1}≈0 or Tp_{(CE/CS)-config1}<<Tp_{(CS/ST)-config2} and Tp_{(CE/CS)-config1}<<Tp_{(ET/CE)-config2},

with

Tp_{(ST/ET)-config1}: the propagation time of a signal in said first configuration between said second input and said first output,

Tp_{(CS/ST)-config2}: the propagation time of a signal in said second configuration between the first input and the first output,

and Tp_{(ET/CE)-config2}: the propagation time of a signal in said second configuration between the second input and the second output, Tp_{(CS/CE)-config1} the propagation time of a signal in said first configuration between the first input and the second output.

By Tp_{(CE/CS)-config1}<<Tp_{(CS/ST)-config2} it is meant that Tp_{(CE/CS)-config1} is at least ten times or at least a hundred times lower than Tp_{(CS/ST)-config2}.

And by Tp_{(CE/CS)-config1}<<Tp_{(ET/CE)-config2} it is meant that Tp_{(CE/CS)-config1} is at least ten times or a hundred times lower than Tp_{(ET/CE)-config2}.

Tp_{(CS/ST)-config2} and Tp_{(ET/CE)-config2} can be for example in the order of several nanoseconds.

Tp_{(CE/CS)-config1} can be for example in the order of several picoseconds, for example in the order of one or several hundreds of picoseconds.

The controlling device may further comprise:
means for, when the configuration selecting module is in the first configuration, determining Tp_{(ET/ST)-config1},
means for, when the configuration selecting module is in the second configuration: determining a Tesbo delay between a test signal, injected into the second input (ET) and having a frequency equal to the resonance frequency of the MEMS or NEMS and a signal in response to this test signal extracted from said first output (ST),

said given delay being selected such that: n/(Fr)−(Tp_{(ET/ST)-config1}−T_{esbo}), where n is an integer and Fr the resonance frequency of the MEMS or NEMS.

The controlling device may further comprise: an output interface provided with charge and/or voltage level adapter means at the output of the programmable delay module.

The present invention also relates to a microelectronic device comprising at least one MEMS or at least one NEMS and a controlling device as previously defined.

### BRIEF DESCRIPTION OF THE DRAWINGS

The present invention will be better understood upon reading the description of exemplary embodiments given purely by way of indicative and non-limiting example, in reference to the accompanying drawings in which:

FIGS. 1A and 1B illustrate a following example of an electrostatic excitation and piezoresistive detection NEMS device,

FIG. 2 illustrates a first example of implementation of a controlling device according to the invention designed to deliver excitation signals to a MEMS or NEMS device, the controlling device being in the form of a feedback loop provided with a digital programmable delay module for imposing a determined phase shift to the excitation signals delivered to the MEMS or NEMS,

FIG. 3 illustrates a second example of implementation of the controlling device according to the invention, the latter being provided with a configuration selecting module configured to place the controlling device in an open loop configuration or a closed loop configuration,

FIG. 4 illustrates an example of implementation of a filtering amplifier chain implemented in an exemplary device according to the invention,

FIG. 5 illustrates an example of comparator implemented in an exemplary device according to the invention,

FIG. 6 illustrates an exemplary embodiment of a programmable delay module within an example of a device according to the invention,

FIG. 7 illustrates an exemplary embodiment of a configuration selecting module within a device according to the invention for controlling the excitation of a MEMS or NEMS, the configuration selecting module being adapted for switching between a first configuration wherein the controlling device is in closed loop and a second configuration wherein the controlling device is in open loop,

FIGS. 8A-8B illustrate the operation of a frequency measurement block within an exemplary device according to the invention,

FIG. 9 illustrates the operation of an output interface of the programmable delay module within an exemplary device according to the invention.

### DETAILED DISCLOSURE OF PARTICULAR EMBODIMENTS

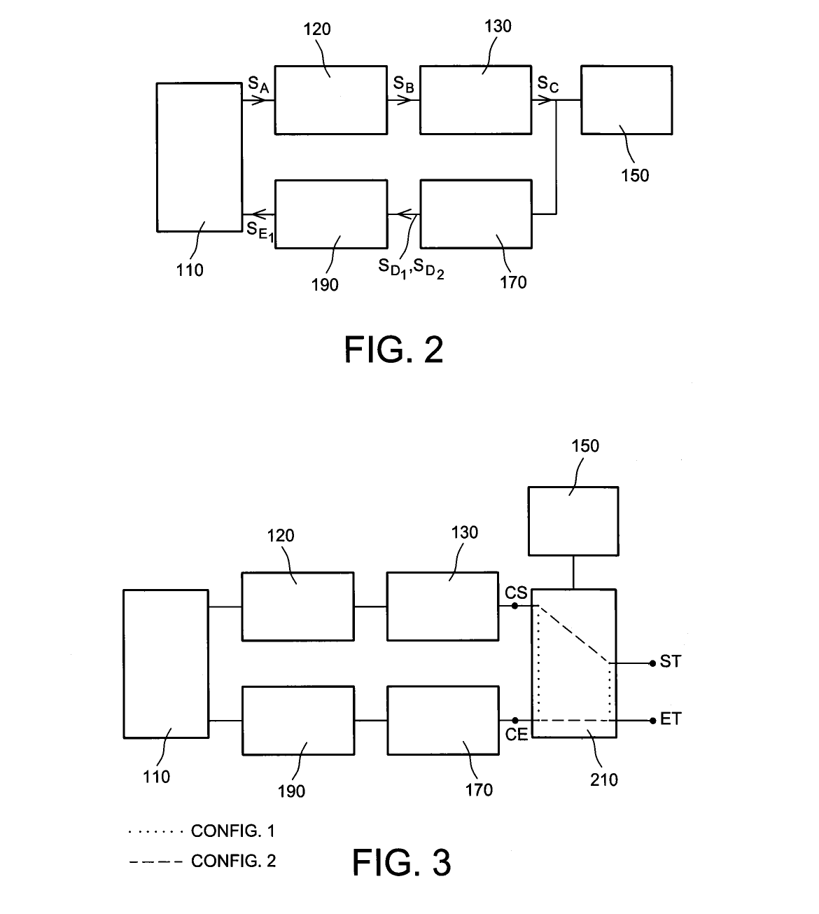

A first exemplary controlling device, implemented according to the invention, is illustrated in FIG. 2.

This controlling device enables an excitation of a MEMS or NEMS to be performed, for example a MEMS or NEMS resonator, in order to oscillate it and/or keep it in oscillation.

The controlling device can be in the form of a feedback loop first comprising a first stage 120 or a module 120 comprising a gain/filtering chain which can be analog and enable a signal S_{A} from a MEMS or NEMS resonator 110 to be amplified.

This chain can be made of a differential amplifier or a transimpedance amplifier or TIA (transimpedance) amplifier and/or one or more low-pass and/or high-pass filters.

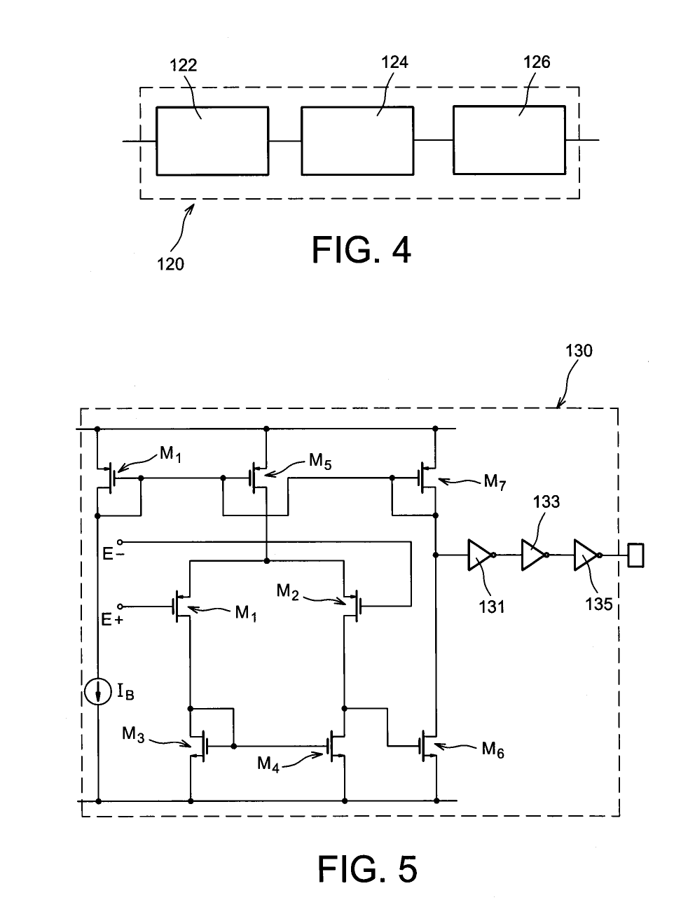

An exemplary embodiment of the gain/filtering chain of the first stage 120 is given in FIG. 4 and comprises a transimpedance amplifier 122, at the output of which are means 124 providing adjustable low-pass filtering. At the output of the means providing adjustable low-pass filtering 124, are also provided means 126 providing adjustable high-pass filtering.

An amplified signal S_{B} thus comes from the first stage 120 and is digitized using digitizing means comprising a voltage comparator 130 which is for example asynchronous.

An exemplary embodiment of such a comparator 130 is given in FIG. 5.

This comparator 130 is referred to as “asynchronous” insofar as it is not sampled by a reference clock. The comparator 130 may comprise a differential amplifier with inputs E+ and E− made of transistors M₁, M₂, M₃, M₄, M₈, M₅. The comparator 130 may also be made of a gain stage comprising transistors M₇, M₆.

The gain stage is followed by a series of inverters 131, 133, 135 for performing a charge matching with the next stage of the controlling device.

At the output of the digitizing means 130, a digital signal S_{c} is delivered. This digital signal S_{c} can be used by a digital block 150 for performing a frequency measurement of the digital signal S_{c}.

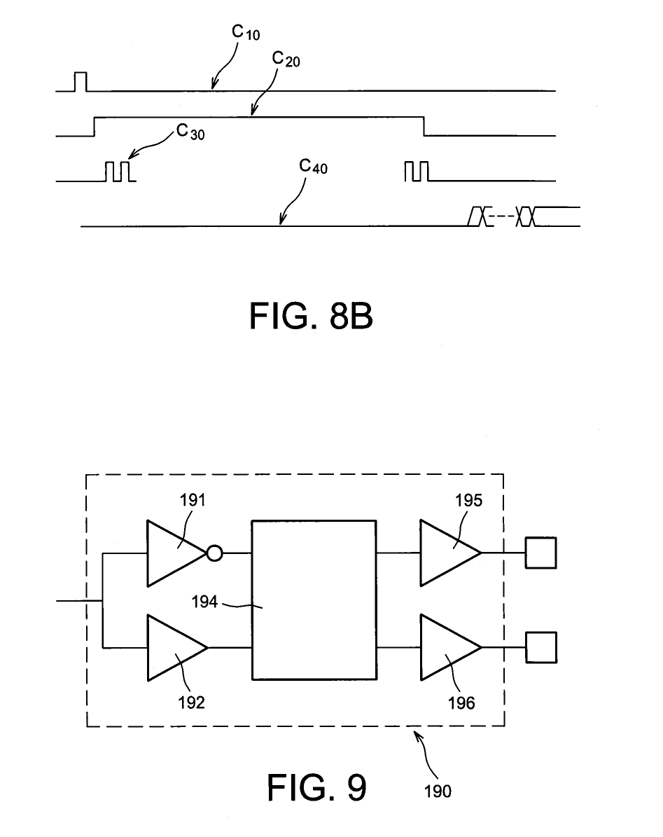

An exemplary embodiment of a frequency measurement block 150 is illustrated in FIG. 8A. The measurement implemented by this block 150 may be a measurement of the average period of oscillation.

The frequency measurement block 150 may be formed by two main modules 153, 155 that can be produced by using synchronous counters.

A first module 155 of the block 150 is a two to the N divider.

On a first input E₂ of the first module 155, a reference signal Href is at a reference frequency F_{REF} for example a value of 1024 MHz.

An output S₂ of this block is a signal Smes of a period Tmes which may be for example 2048 μs and have for example a high level of duration in the order of 1024 μs when N=21.

An AND gate 151 receives the digital signal Sc on a first input and the signal Smes from the first module 155 on a second input. This AND gate 151 delivers a signal to an input E₁ of a second module 153 of the block 150.

The second module 153 of the block 150 is made of a synchronous counter, for example triggered on the rising edge, that is to say, at each rising edge applied to its input E₁, the value stored in the counter is incremented by one unit.

Another input RAZ of the second module 153 is used to reset the value of the counter. An output S₁ enables the current counter value to be delivered.

Timing diagrams C₁₀, C₂₀, C₃₀, C₄₀, respectively representative of the reset signal RAZ of the second module 153, of the output signal Smes of the first module 155, of the output signal of the AND gate delivered at the input E₁ of the second module 153, of the data signal at the output of the second module 153 are given in FIG. 8B, and show the operation of the frequency measurement module 150.

The measurement can be carried out in 3 phases:

In a first phase called “initialization”, the synchronous counter 153 is initialized via the reset signal RAZ.

In a second phase called “counting”: when the signal Smes at the output of the first module 155 is in a high state or equal to a logical level ‘1’, at each rising edge of the digital signal, the value of the counting implemented by the second module 153 is incremented.

In a third phase of transfer and computation: when the signal Smes at the output of the first module 155 returns to a low state or a logical level ‘0’, the value M of the counter 153 is transferred to a computing unit;

the computation of an average period Txm of a digital signal can be performed using a formula: Txm=(0.5*Tmes)/M.

For example, with a value of reference frequency F_{REF} of the clock signal of 1024 MHz, for N=21, the period of Tmes is 2048 μs and the duration of the high level of 1024 μs.

For example for M=20000, Txm=0.5*2048 μs/20000=51.2 ns is computed.

For M=20001, Txm=0.5*2048 μs/20001=51.19744 ns is computed.

A periodic or permanent measurement can be implemented. The result of this measurement can be stored in a memory.

The digital signal S_{c} is also injected into a module 170 forming a programmable delay cell for example to generate one or more digital output signals S_{D1}, S_{D2} with a known delay with respect to the input signal S_{c}, this delay being adjustable or programmable, and selected from a plurality of predetermined delays.

The delay introduced in the feedback loop enables to compensate for that generated by the other elements of the loop and deliver an excitation signal or signals to the resonator according to a determined phase difference fulfilling the oscillation conditions of the resonator.

The module 170 enables a delay independent of the frequency of the signal detected at the output of the MEMS or NEMS to be induced. The module 170 also enables a delay without attenuation of the signal entering this module to be induced.

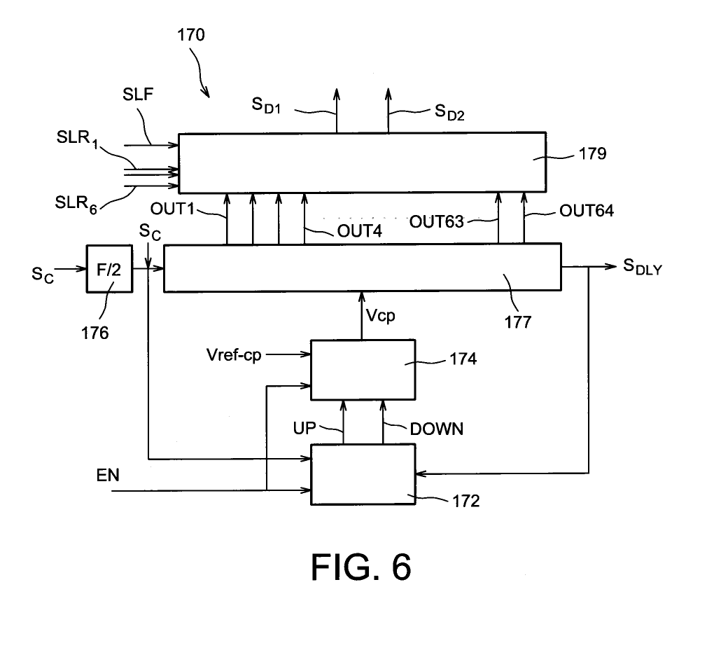

The programmable delay module 170 may be formed using a DLL (“Delay Locked Loop”) architecture such as that shown for example in FIG. 6.

In this exemplary embodiment, the module 170 includes a phase comparator 172, a charge pump 174, a voltage-controlled delay line 177 and a decoder 179.

The phase comparator 172, when activated by a signal EN compares the input signal S_{C} acting as a reference signal and a signal Sdly corresponding to the last signal generated at the end of the delay line 177. The phase comparator 172 delivers two logical signals UP and DOWN, which are the image of the phase shift between the two signals S_{C} and Sdly to be synchronized. When the two signals Sc and Sdly are not yet synchronized, the logical signals UP and DOWN have different durations. When the two signals S_{C} and Sdly are in phase, the loop is locked.

The duration difference between the UP and DOWN signals is converted by the charge pump 174 into a proportional voltage Vcp which controls the delay line 177.

The decoder 179 may in turn be provided with a plurality of selecting inputs, for example, k=6 bit inputs SLR₁, . . . , SLR₆ of the decoder 179 to select a delay value among several ones, in particular 2^{k}, determined delay values, for example 2⁶ available delayed signals delivered by the delay line 177.

This delay line 177 receives as an input the signal S_{C} delivered by the previous stage of the loop as well as the DC voltage Vcp delivered by the charge pump 174 converter.

The delay line 177 is thus likely to deliver several, in particular 2^{k}, determined delayed signals, for example 2⁶ delayed signals to the outputs OUT1, . . . , OUT64, of the delay line 177 respectively.

A first output OUT1, when selected, enables for example a zero delay to be delivered, while a 64^{th} output OUT64, when selected, enables for example a delay equal to the period of the signal Sc for example 50 ns, to be delivered and the intermediate outputs can deliver for example a delay of between 0.1 ns and 50 ns, for example in the order of 20 ns.

The decoder 179 allows to select a M^{th} given output OUT_{M} from the outputs OUT1, . . . , OUT64, of the delay line 177 and deliver a first signal S_{D1} from this given output OUT_{M} according to the order indicated by the selecting signals SLR₁, . . . , SLR₆.

The decoder 179 may also be provided for outputting a second signal S_{D2} having a frequency and an amplitude equal to those of the first signal S_{D1} but phase-shifted with respect to S_{D1} by a predetermined phase shift, for example in phase quadrature or in a phase opposite to that of the first signal S_{D1} according to the selected excitation mode of the resonator.

A first excitation mode of the resonator 110 in which a signal is applied to the resonance frequency Fr of phase 0° of said first so-called “excitation” pad of the MEMS or NEMS resonator and a signal equal to half the resonance frequency Fr/2 of a phase 180° on a second so-called “excitation” pad of the MEMS or NEMS resonator 110 may be provided.

A second excitation mode of the resonator can be provided so that it applies a signal S_{E1} of frequency Fr/2 and phase 0° on the first pad of the resonator and a signal S_{E2} at Fr/2 of phase 90° to the second excitation pad. This second excitation mode enables the gain to be maximized.

At the delay module 170, switching from the first excitation mode of the second excitation mode can be enabled using a selection bit SL_{F} of the decoder 179.

In the first excitation mode, the signals S_{D1} and S_{D2} output from the delay module 170 may respectively have a phase of (360°*M)/64 and a phase of) ((360°*M/64)+180° and an excitation frequency Fe.

In the second excitation mode, the signals S_{D1} and S_{D2} may respectively have a phase of (360°*N)/64 and a phase of)((360°*N)/64+90° and a frequency equal to Fe/2.

With such a module 170, the delay or phase shift introduced is adjustable in a wide range of delays or phase shifts and valid whatever the phase shifts introduced by each block or module of the feedback loop.

With such a module 170, the amplitude of the signals S_{D1} and S_{D2} does not vary as a function of the frequency range within which lies the resonance frequency of the MEMS 110 or NEMS 110.

With such a module 170, a locked delay which is independent of the supply voltages of the controlling device is introduced.

The delayed signal(s) S_{D1}, S_{D2} output from the programmable delay stage 170 may then be shaped by an output interface module 190 to be applied to excitation means 110 of the resonator.

This shaping module 190 can generate signals S_{E1} S_{E2} having voltage levels adapted to the resonator and serving as excitation signals for actuating the resonator.

The output interface module 190 allows to adapt in level or charge the output signal(s) S_{D1}, S_{D2} of the programmable delay module 170 to means for exciting the resonator. This output interface 190 may be produced using one or more inverters and one or more level translators.

An exemplary embodiment of an output interface module 190 is given in FIG. 9.

This module may be made of buffer memories commonly known as input “buffers” 191, 192, for receiving digital signals according to a first range of amplitudes or voltages, for example, in the order of 1 volt, from a translator level 194 provided to deliver amplitude-enhanced signals to output buffers 195, 196. The module 190 is provided for transmitting signals in a second range of voltages or amplitudes higher than the first range and for example in the order 3 volts.

The module 190 receives digital signals and delivers digital or analog signals. Digital to analog conversion is performed internally or at the output of the module 190, for example by filtering.

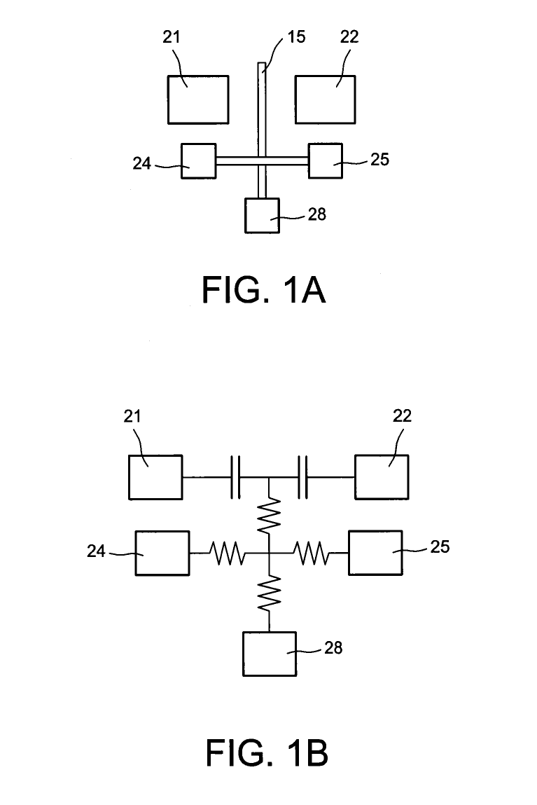

In one case, for example, where the resonator 110 is of the type described in connection with FIGS. 1A-1B, the signals S_{E1} S_{E2} are delivered to the excitation pads 21 and 22 located near the movable element 15.

To hold oscillation conditions, the programmable delay module enables a constant phase shift to be established between the input of the first stage and the excitation signals S_{E1}, S_{E2}.

An alternative embodiment of the controlling device previously described is given in connection with FIG. 3.

For this alternative, the controlling device comprises, between the digitizing means 130 and the delay unit 170, a configuration selecting module 210 suitable for switching between a first configuration wherein the feedback loop has a first configuration or a first arrangement, and a second configuration wherein the feedback loop has a second configuration or a second arrangement.

The first configuration may enable the controlling device to be placed in a closed loop configuration while the second configuration may be intended to place the device in an open loop configuration.

The configuration selecting module 210 comprises a first input CS connected to the output of the comparator 130 and a second input ET on which a test signal is to be applied.

The configuration selecting module 210 is also provided with a first output ST from which a test signal is to be extracted and a second output CE connected to the programmable delay module 170.

The configuration selecting module 210 is provided to adopt a first configuration wherein the first input CS is connected to the first output ST and the second input ET is connected to the second output CE. The configuration selecting module 210 is also provided to assume a second configuration in which the first input CS is connected to the second output CE, the second input ET being connected to the first output ST.

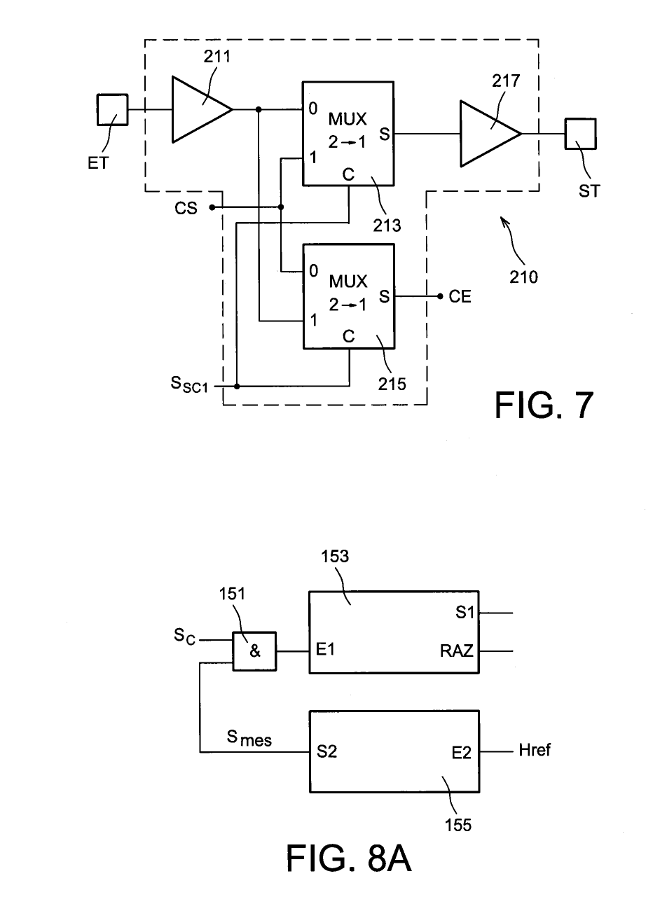

An example of implementation of such a configuration selecting module is given in FIG. 7.

Switching from the first configuration to the second configuration can be achieved depending on the state of a configuration selecting logical signal S_{sc}.

This module 210 may be formed from 2 to 1 multiplexers, 213 and 215 and buffers 211, 217.

On its first input CS, the module 210 is likely to receive a digital signal Sc from the comparator 130. The first input CS of the module 210 is connected to an input ‘1’ of a first 2-to-1 type multiplexer 213, whereas the second input ET of the module 210 is connected via the buffer 211 to an input, ‘0’ of the first multiplexer 213. This first multiplexer 213 is provided to transmit at the output S one of its two inputs CS and ET, for example according to the following truth table:

| | |
|---|---|
| sc | |
| | T |
| | S |

A further buffer 217 is provided at the output of the first multiplexer 213.

The first input CS of the module 210 is also connected to an input ‘0’ of a second 2-to-1 type multiplexer 215, while the first input ET of the module 210 is connected to an input ‘1’ of the second multiplexer 215. The second multiplexer 215 is also provided to transmit at the output S one of its two inputs CS and ET, for example by following the following truth table.

| | |
|---|---|
| sc | |
| | S |
| | T |

The module 210 can thus follow the truth table below:

| Configuration | Output ST | Output CE |
|---|---|---|
| Configuration 1 | Input ET | Input CS |
| Configuration 2 | Input CS | Input ET |

The configuration selecting module 210 may also be produced so that, and in particular the buffers 211 and 217 may be provided so that the propagation delays between the inputs ET, CS and the outputs ST, CE fulfil the following relationships r1 and r2:

Tp_{(ET/ST)-config1}=Tp_{(CS/ST)-config2}+Tp_{(ET/CE)-config2} (r1)

with:
Tp_{(ET/ST)-config1}, the propagation time of a signal in configuration 1 of the module 210 between the input ET and the output ST,
Tp_{(CS/ST)-config2}, the propagation time of a signal in configuration 2 of the module 210 between the input CS and the output ST,
Tp_{(ET/CE)-config2}, the propagation time of a signal in configuration 2 between the input ET and the output CE,

Tp_{(CS/CE)-config1}≈0, or

Tp_{(CS/CE)-config1}<<Tp_{(CS/ST)-config2} and

Tp_{(CS/CE)-config1}<<Tp_{(ET/CE)-config2} (r2)

By Tp_{(CS/CE)-config1}<<Tp_{(CS/ST)-config2}, it is meant that Tp_{(CS/CE)-config1} is provided at least ten times or at least a hundred times lower than Tp_{(CS/ST)-config2}.

By Tp_{(CS/CE)-config1}<<Tp_{(ET/CE)-config2} it is meant that Tp_{(CS/CE)-config1} is provided at least ten times or at least a hundred times lower than Tp_{(ET/CE)-config2}.

Tp_{(CS/ST)-config2} and Tp_{(ET/CE)-config2} can be for example in the order of several nanoseconds.

Tp_{(CS/CE)-config1} may for example be in the order of several picoseconds for example in the order of one or several hundreds of picoseconds.

Using this configuration selecting module 210, it is possible to conduct an evaluation of the delay or phase shift introduced by the module 170 and which is intended to be selected so as to allow to provide oscillating the resonator and/or hold oscillation thereof.

A method for determining the delay or phase shift to be selected and produced by the module 170 can be the following one:

First the resonance frequency Fr of the resonator 110 is determined by one or more prior actions.

The resonance frequency Fr can be determined, for example, by a direct measurement on the MEMS or NEMS. In the case where the resonator studied is of the type described in relation to FIG. 1, the measurement can be performed on the detection pad 28 of the latter. A determination of the local maximum of the transfer function enables the resonance frequency Fr to be indicated.

Then, the configuration selecting module 210 is placed in the first configuration to determine the delay Tes=Tp_{(ET/ST)-config1} between the second input ET of the module 210 and the first output ST, for example using a test signal.

Then, the programmable delay block 170 is programmed so as to introduce a zero delay, while the configuration selector 210 is placed in the second configuration.

A Tesbo delay is then determined between the second input ET and the first output ST when the configuration selecting module 210 is in the second configuration and the controlling device is in open loop.

For this, a frequency signal equal to the resonance frequency Fr previously determined is injected.

The Tesbo delay is such that:

Tesbo=Tp_{(CS/ST)-config2}+Tp_{(ET/CE)-config2}+Tbo

with Tbo being the delay generated by the rest of the modules and circuits of the device.

The Tbo delay is deduced by the relationship Tbo=Tesbo−Tes (if relationship r1 holds).

The ideal delay Ti to be generated by the programmable delay block is determined to ensure that:

T₁=n/F−Tbo

where n is a positive integer, with F the frequency of the signal at the input of the device close to or equal to Fr, the resonance frequency of the resonator NEMS, so that:

T₁=n/Fr−Tbo.

Then a “possible” delay Tr is determined from the whole of programmable delays of the delay module. The delay Tr is chosen equal to k*(Tdelay max/total number of elementary delays), where k is an integer corresponding to the number of elementary delays selected by the value of the input SLF (Tdelay max being equal to or 1/Fr or a multiple of 1/Fr). The number k of retained elementary delays is such that Tr is as close as possible to T1, wherein Tr may be selected below or above T1.

One or more of these steps can be performed by means of a microprocessor associated with one or more digital processing modules, or by means of a data processing device, for example a computer.

After adjusting the delay (SLF), the configuration selecting module 210 is placed in the first configuration, so as to be placed in a closed loop. The first input ET can then be set to a defined state.

Oscillating the resonator can thus be ensured.

According to an alternative embodiment, it could be possible to use other types of circuits to produce a programmable delay module. For example in the case where a high frequency clock signal is available, N times higher than the resonance frequency of the resonator, it will be possible to provide a programmable delay circuit by using a counter by N.

According to another alternative embodiment, a digital delay can be implemented by providing a register whose data are managed in FIFO mode. For a frequency signal, for example in the order of 20 MHz, a register length for example of 50 clocked by a clock at 1 GHz may be provided.

Means for selecting an output of the register, for example as a multiplexer, enable to select an intermediate output of rank i, the signal outputted has a delay ΔT=i*1n=i/1E9 that is a phase shift Δφ=i*360*20e6/1E9, the register width used in the FIFO being identical to the number of bits of the analog digital converter.

1. A device for controlling a micro-electromechanical system MEMS or a nano-electromechanical system NEMS comprising a feedback loop provided with:
means (130) for digitizing at least one analog signal from said MEMS or said NEMS and for delivering a digital signal,
a programmable delay module (170) for inducing a delay selected from a plurality of predetermined delays to said digital signal and delivering one or more delayed digital signals to excitation means of the MEMS or NEMS.

2. The device for controlling a micro-electromechanical MEMS or NEMS according to claim 1, wherein among said delayed digital signals are a first signal (S_{D1}) and a second signal (S_{D2}) having a frequency equal to the resonance frequency of the MEMS or NEMS, the first signal and the second signal being in opposite phases.

3. The device for controlling a micro-electromechanical MEMS or NEMS according to claim 1, wherein from said delayed digital signals (S_{D1}, S_{D2}) are a first and a second frequency signals having a frequency equal to half the resonance frequency of the MEMS or NEMS, the first and the second signal being in phase quadrature.

4. The controlling device according to claim 1, wherein the programmable delay module (170) comprises:
means (177) for delivering a plurality of signals (OUT1, . . . , OUT64) phase-shifted with respect to an input signal (Sc) of said delay unit, said signals being phase-shifted respectively by a plurality of predetermined phase shifts,
selecting means (179-SLR₁, . . . , SLR₆) for selecting at least one phase-shifted signal from said plurality of phase-shifted signals,
frequency selecting means (179-SLF) between a frequency equal to the frequency of said input signal and a frequency equal to half the frequency of said input signal,
the signal(s) output from said programmable delay module (170) having a phase shift equal to the phase shift of said phase-shifted signal and a frequency equal to the frequency or half the frequency of said input signal.

5. The controlling device according to claim 4, wherein the programmable delay module (170) comprises means (172, 174) forming a phase locked loop,
the means (177) for delivering a plurality of phase-shifted signals comprising a voltage-controlled delay line having a first input receiving said first digital signal and delivering a feedback signal (Sdly), the control voltage of the delay line depending on a difference between said digital signal and said feedback signal (Sdly).

6. The controlling device according to claim 1, further comprising means (150) for measuring the frequency of said digital signal (Sc).

7. The controlling device according to claim 1, further comprising a configuration selecting module (210) provided with a first input (CS) connected to the digitizing means (130) and a second input (ET), the configuration selecting module (210) being also provided with a first output (T) and a second output (CE) connected to the programmable delay module (170), the configuration selecting module being adapted to assume:
a first configuration in which the first input (CS) is connected to the second output (CE), the second input (ET) being connected to the first output (ST),
a second configuration in which the first input (CS) is connected to the first output (ST), the second input (ET) being connected to the second output (CE).

8. The controlling device according to claim 7, wherein the configuration selecting module is provided such that:
Tp_{(ET/ST)-config1}=Tp_{(CS/ST)-config2}+Tp_{(ET/CE)-config2},
10*Tp_{(CE/CS)-config1}<Tp_{(CS/ST)-config2}, and
10*Tp_{(CE/CS)-config1}<Tp_{(ET/CE)-config2},
with Tp_{(ST/ET)-config1}, the propagation time of a signal in said first configuration between said second input (ET) and said first output (ST), Tp_{(CS/ST)-config2}, the propagation time of a signal in said second configuration between the first input (CS) and the first output (ST), and Tp_{(ET/CE)-config2}, the propagation time of a signal in said second configuration between the second input (ET) and the second output (CE), Tp_{(CS/CE)-config1} the propagation time of a signal in said first configuration between the first input (CS) and the second output (CE).

9. The controlling device according to claim 8, comprising:
means for, when the configuration selecting module is in the first configuration, determining Tp_{(ET/ST)-config1},
means for, when the switch configuration module is in the second configuration: determining a Tesbo delay between a test signal, injected into the second input (ET) and which frequency is equal to the resonance frequency of the MEMS or NEMS and a signal in response to this test signal extracted from said first output (ST),
said given delay being selected such that: n/(Fr)−(Tp_{(ET/ST)-config1}−T_{esbo}), with n an integer and Fr the resonance frequency of the MEMS or NEMS.

10. The controlling device according to claim 1, further comprising: an output interface (190) having charge and/or voltage level adapter means at the output of the programmable delay module (170).

11. A microelectronic device comprising at least one MEMS or NEMS and a controlling device according to claim 1.
